(19) United States
(12) Patent Application Publication
(10) Pub. No.: US 2014/0175380 A1
(43) Pub. Date: Jun. 26, 2014

(54) SUPERCONDUCTING SINGLE FLUX QUANTUM INTEGRATED CIRCUIT DEVICE

(71) Applicant: INTERNATIONAL SUPERCONDUCTIVITY TECHNOLOGY CENTER, Kawasaki-shi (JP)

(72) Inventors: Hideo Suzuki, Tokyo (JP); Keiichi Tanabe, Tokyo (JP)

(73) Assignee: INTERNATIONAL SUPERCONDUCTIVITY TECHNOLOGY CENTER, Kawasaki-shi (JP)

(21) Appl. No.: 14/192,717

(22) Filed: Feb. 27, 2014

Related U.S. Application Data
(63) Continuation of application No. PCT/JP2012/070904, filed on Aug. 17, 2012.

(30) Foreign Application Priority Data
Sep. 9, 2011 (JP) 2011-197563
Sep. 9, 2011 (JP) 2011-197572

(51) Int. Cl. H01L 27/18

(52) U.S. Cl. CPC H01L 27/18
USPC 257/31

(57) ABSTRACT

The present invention relates to a superconducting single flux quantum integrated circuit device, and eliminates the return current from a bias current and the effect the bias current itself has on SFQ logic circuits in a chip. A bias power source line for supplying a DC bias current for the superconducting single flux quantum integrated circuit in a chip and a bias drawing power source line for drawing said DC bias current to the outside of the chip are provided, the end of the bias drawing power source line is connected to the ground plane of the chip via a thin-film resistor having a plurality of resistance values of 0.1 milliohm to I milliohm near the superconducting single flux quantum integrated circuit laid out in the chip, and the DC bias current is drawn from a connection point with the ground plane.

### CROSS-REFERENCE TO RELATED APPLICATIONS

This application is a continuation of International Application No. PCT/JP2012/070904, filed on Aug. 17, 2012, now pending, herein incorporated by reference. Further, this application is based upon and claims the benefit of priority from the prior Japanese Patent Application No. 2011-197563, filed on Sep. 9, 2011, and the prior Japanese Patent Application No. 2011-197572, filed on Sep. 9, 2011, entire contents of which are incorporated herein by reference.

### TECHNICAL FIELD

The present invention relates to a superconducting single flux quantum integrated circuit device, and to a structure for eliminating the effects of bias currents in a superconducting single flux quantum integrated circuit, such as a superconducting A/D converter or a superconducting D/A converter which uses a single flux quantum (SFQ) circuit, or a superconducting digital circuit.

### BACKGROUND ART

In a superconducting single flux quantum (SFQ) circuit, logic calculations and signal processing using SFQ pulses are carried out at high speed by using SFQ as an information carrier (see, for example, Non-Patent Literature 1). The integrated circuit chip employs a superconducting ground called a ground plane, and the ends of nearly all of the Josephson junctions which constitute a logic gate are connected to the ground plane.

A SFQ superconducting loop is formed passing through this superconducting ground plane. Furthermore, this superconducting ground plane is used to form a transmission line such as a micro-strip line or strip line for signal transmission between logic gates which are distant from each other in a chip.

Normally, the superconducting ground plane is disposed on the lower surface or the upper surface of the whole circuit, over the whole surface of the integrated circuit chip. Furthermore, a DC bias current is supplied to the SFQ logic gate and then flows to the common superconducting ground.

An integrated circuit, such as a superconducting A/D converter or superconducting SFQ digital circuit is composed by combining various analog circuits and logic gates, such as comparators, OR, AND, NOT, XOR, DFF, TFF, etc. Furthermore, a passive transmission line (PTL) such as micro-strip line or a strip line, which is capable of high-speed communication, is used for transmission of SFQ pulse signals between gates which are a relatively large distance apart, such as 100 μm or more, within a chip.

This SFQ integrated circuit is manufactured by a multi-layer thin-film technology including superconducting material and insulating material. The SFQ integrated circuit is normally manufactured on a superconducting ground plane in order to reduce inductance and in order to convey high-speed SFQ pulses. This superconducting ground plane constitutes a superconducting loop in combination with superconducting wires, by using Josephson junctions as switching elements in the SFQ integrated circuit.

FIG. 23 is an illustrative diagram of a bias current supply system for a conventional SFQ integrated circuit, and in this SFQ integrated circuit, one end is connected to the superconducting ground plane, and a superconducting loop is formed passing through the ground. The superconducting ground plane is disposed on the lower surface or the upper surface, or both the upper and lower surfaces, of the whole circuit, over the whole surface of the SFQ integrated circuit chip. Normally, the superconducting ground plane is provided on the lower surface of the circuit, in other words, on the substrate side of the integrated circuit chip.

In an SFQ integrated circuit, a bias current is supplied to the SFQ logic gate 91 and the analog circuit, which are these constituent elements, from a DC bias power source line 92 formed from a superconducting wire in the SFQ logic gate 91, via a bias resistance 93. Since the DC voltage of the DC bias power source line 92 is kept at a fixed voltage without resistance loss, by using a superconducting wire, then a bias current which is determined by the power source voltage and the bias resistance 93 is supplied to the SFQ logic gates 91. Furthermore, normally, a pad (bonding pad) for connecting with an external circuit connected to the DC bias power source line 92, a pad for input and output signals, and a pad for connecting the ground inside the chip and the ground outside the chip, are arranged at the periphery of the integrated circuit chip.

The voltage of the DC bias voltage source line is set to 2.5 mV, for example, and a suitable bias current is supplied to the SFQ logic gates 91 via the bias resistance 93 and ultimately flows to the ground plane. If the supplied bias current is large, then the DC bias power source line 92 is connected to a plurality of pads as appropriate, so as to distribute and supply the adequate current.

The superconducting ground plane is arranged on the whole lower surface of the circuit, over the whole surface of the integrated circuit chip, and therefore after flowing through the common superconducting ground plane, the supplied DC bias current flows to a ground outside the chip via a ground pad.

The gate design of the SFQ integrated circuit and the layout on the chip can be designed freely, in other words, can be customized, but a cell-based design technique which has good reproducibility and enables easy design has been developed for designing functional circuits which are possible with normal logic gates.

FIG. 24A and FIG. 24B are plan diagrams of one example of a cell (called a CONNECT cell) of a SFQ circuit using a cell-based design. As depicted in FIG. 24A, the SFQ logic gate is designed in units which are called “cells” which are same size, and the layout is based on standardized input/output and bias power source line wiring (see, for example, Non-Patent Literature 2).

In a CONNECT cell, a large number of logic cells having various functions are designed, a bias power source line is also wired inside the cells, and a bias line is connected with adjacent cells in common fashion. In other words, a mesh-shaped bias power source line is formed inside a block in which the cells are arranged.

Furthermore, as depicted in FIG. 24B, in addition to these logic gate cells, moat cells for the bias power source and for avoiding circuit malfunction by trapping unwanted magnetic fields are also prepared. By suitably arranging these cells, an integrated circuit having appropriate functions can be designed freely.

FIG. 25 is a conceptual diagram of a conventional layout, and normally, the moat cells for the bias power source are arranged around the periphery, and bias power source lines from the chip pad are connected to these moat cells. In this case, in order to avoid concentrated flow of the bias current, the supply path of the bias current is broadened by stacking the moat cells in multiple levels, as appropriate.

Moreover, the bias power source lines are connected at a plurality of points, as indicated by the bias power source lines from the left side in FIG. 25, and bias current is supplied from these contact points. Therefore, it is possible to avoid concentration, in a particular logic cell, of the bias current flowing inside the logic cells which are arranged in a block shape.

Meanwhile, the supplied DC bias current returns to outside the chip via the ground plane, but the current path flowing in the ground plane inside the chip is not controlled. Since this current is small in small-scale circuits, then the magnetic field created thereby is also small, and the effects thereof on the SFQ circuit can be ignored. On the other hand, as the circuit becomes larger in scale, the magnetic field created by the ground current links with the SFQ circuit, and problems such as malfunction, occur.

In order to reduce the effects of return current from the DC bias current of this kind, a method has been proposed in which the bias current is drawn out from ground pads which are adjacent to the DC bias power source line pads provided around the periphery of the chip (see, for example, Non-Patent Literature 3).

FIG. 26A and FIG. 26B are conceptual diagrams of one example of a conventional DC bias current drawing layout, in which FIG. 26A is a conceptual diagram of a case where a SFQ circuit is taken to be a single large-scale circuit, and FIG. 26B is a conceptual diagram of a case where a SFQ circuit is divided into small-scale functional blocks. In either of these cases, bias power source supply pads and bias current drawing pads are provided adjacently to the bias power source supply pads, and the magnetic fields by both currents flowing therein cancel each other out by setting both currents to be identical.

### CITATION LIST

### Non-Patent Literature

Non-Patent Literature 1: K. K. Likharev and V. K. Semenov, “RSFQ Logic/Memory Family: A new Josephson-Junction Technology for Digital Systems,” IEEE Trans. Appl. Supercond., Vol. 1, March 1991

Non-Patent Literature 2: S. Yorozu, et. al, “A single flux quantum standard logic cell library”, Physica C: Superconductivity, vol. 378-381, part 2, pp. 1471-1474, October 2002

Non-Patent Literature 3: Hirotaka Terai, et. al., “Signal integrity in large-scale single-flux-quantum circuit”, Physica C: Superconductivity, vol. 445-448, part 2, pp. 1003-1007, 2006

Non-Patent Literature 4: S. Nagasawa, et. al., “A 380 ps 9.5 mW Josephson 4-Kbit RAM Operated at a high Bit Yield”, IEEE Trans. On Appl. Supercond., Vol. 5, pp. 2447-2452, 1995

### SUMMARY OF INVENTION

### Problems to be Solved by the Invention

However, in a conventional layout, for example, there is a difference between the flow path of the bias current supplied from the bias power source line to logic cells using a cell-based design, and the flow path of the bias current flowing in the ground, towards the ground pads for drawing bias current which are provided at the periphery of the chip. Consequently, it is difficult to cancel out these bias currents inside the circuit, and furthermore there is a problem in that the path of the current flowing in the ground plane is not able to be controlled and this current adversely affects the SFQ circuit.

FIG. 27A and FIG. 27B are illustrative diagrams of the path of the return current of the DC bias current flowing in the ground plane in a conventional layout, and FIG. 27A and FIG. 27B respectively correspond to FIG. 26A and FIG. 26B; there are many varied paths of the return current from the bias current flowing to the ground.

Consequently, it is an object of the present invention to eliminate the effects of the return current from the bias current, and the bias current itself, on the SFQ logic circuits inside the chip.

### Means for Solving the Problems

One aspect of the disclosure provides a superconducting single flux quantum integrated circuit device, including: a bias power source line which supplies a DC bias current to a superconducting single flux quantum integrated circuit in a superconducting single flux quantum integrated circuit chip, from outside the superconducting single flux quantum integrated circuit chip; a bias drawing power source line for drawing the DC bias current to the outside of the superconducting single flux quantum integrated circuit chip; wherein an end of the bias drawing power source line is connected to a ground plane of the superconducting single flux quantum integrated circuit chip via a plurality of resistors formed from thin-film resistors having a resistance value of 0.1 mΩ to 1Ω, at the periphery of a superconducting single flux quantum integrated circuit which is laid out in the superconducting single flux quantum integrated circuit chip, and the DC bias current is drawn out from a contact point with the ground plane.

Moreover, a further aspect of the disclosure provides a superconducting single flux quantum integrated circuit device, including: a main superconducting ground plane of a superconducting single flux integrated circuit chip; a local superconducting ground plane separated from the main superconducting ground plane; a superconducting single flux integrated circuit formed on the local ground plane; film resistors connected between the main superconducting ground plane and the local superconducting ground plane, and having a total resistance value of 1 μΩ to 0.1Ω; and a bias power source line which supplies a DC bias to the superconducting single flux integrated circuit.

### Advantageous Effects of the Invention

According to the disclosed superconducting single flux quantum integrated circuit device, it is possible to eliminate the effects of the return current from the bias current, and the bias current itself, on the SFQ logic circuits inside the chip.

### BRIEF DESCRIPTION OF DRAWINGS

FIG. 1A and FIG. 1B are illustrative schematic drawings of a superconducting single flux quantum integrated circuit device according to an embodiment of the present invention;

FIG. 2A and FIG. 2B are further illustrative schematic drawings of a superconducting single flux quantum integrated circuit device according to the embodiment of the present invention;

FIG. 3A and FIG. 3B are further illustrative schematic drawings of a superconducting single flux quantum integrated circuit device according to the embodiment of the present invention;

FIG. 4A and FIG. 4B are further illustrative schematic drawings of a superconducting single flux quantum integrated circuit device according to the embodiment of the present invention;

FIG. 5 is a conceptual schematic drawing of a superconducting single flux quantum integrated circuit device according to a first example of the present invention;

FIG. 6 is a conceptual schematic drawing of a superconducting single flux quantum integrated circuit device according to a second example of the present invention;

FIG. 7 is a conceptual schematic drawing of the vicinity of one functional circuit block in a superconducting single flux quantum integrated circuit device according to a third example of the present invention;

FIG. 8 is a conceptual schematic drawing of the vicinity of one functional circuit block in a superconducting single flux quantum integrated circuit device according to a fourth example of the present invention;

FIG. 9 is a cross-sectional diagram of a superconducting single flux quantum integrated circuit device according to a fifth example of the present invention;

FIG. 10A to FIG. 10C are illustrative schematic drawings of a thin-film resistor constituting a superconducting single flux quantum integrated circuit device according to a fifth example of the present invention;

FIG. 11 is an overall schematic drawing of the layout of a superconducting single flux quantum integrated circuit device according to a sixth example of the present invention;

FIG. 12A to FIG. 12C are schematic drawings of the layout of respective functional circuit blocks of the superconducting single flux quantum integrated circuit device according to a sixth example of the present invention;

FIG. 13 is a conceptual schematic drawing of a superconducting single flux quantum integrated circuit device according to a seventh example of the present invention;

FIG. 14 is a conceptual schematic drawing of a superconducting single flux quantum integrated circuit device according to an eighth example of the present invention;

FIG. 15 is a conceptual schematic drawing of the vicinity of one functional circuit block in a superconducting single flux quantum integrated circuit device according to a ninth example of the present invention;

FIG. 16 is a conceptual schematic drawing of the vicinity of one functional circuit block in a superconducting single flux quantum integrated circuit device according to a tenth example of the present invention;

FIG. 17 is a cross-sectional diagram of a superconducting single flux quantum integrated circuit device according to an eleventh example of the present invention;

FIG. 18A to FIG. 18C are illustrative schematic drawings of a thin-film resistor constituting a superconducting single flux quantum integrated circuit device according to an eleventh example of the present invention;

FIG. 19 is an illustrative schematic drawing of a transmission line used in a superconducting single flux quantum integrated circuit device according to a twelfth example of the present invention;

FIG. 20 is an illustrative schematic drawing of a transmission line used in a superconducting single flux quantum integrated circuit device according to a thirteenth example of the present invention;

FIG. 21 is an overall schematic drawing of the layout of a superconducting single flux quantum integrated circuit device according to a fourteenth example of the present invention;

FIG. 22A and FIG. 22B are schematic drawings of the layout of respective functional circuit blocks of the superconducting single flux quantum integrated circuit device according to a fourteenth example of the present invention;

FIG. 23 is an illustrative diagram of a bias current supply method for a conventional SFQ integrated circuit;

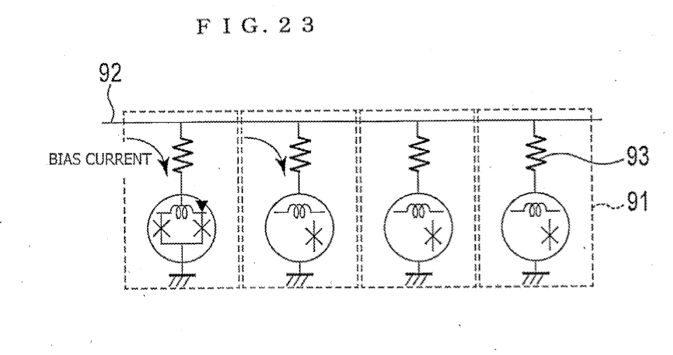

FIG. 24A and FIG. 24B are plan diagrams of one example of a cell of an SFQ circuit according to a cell-based design;

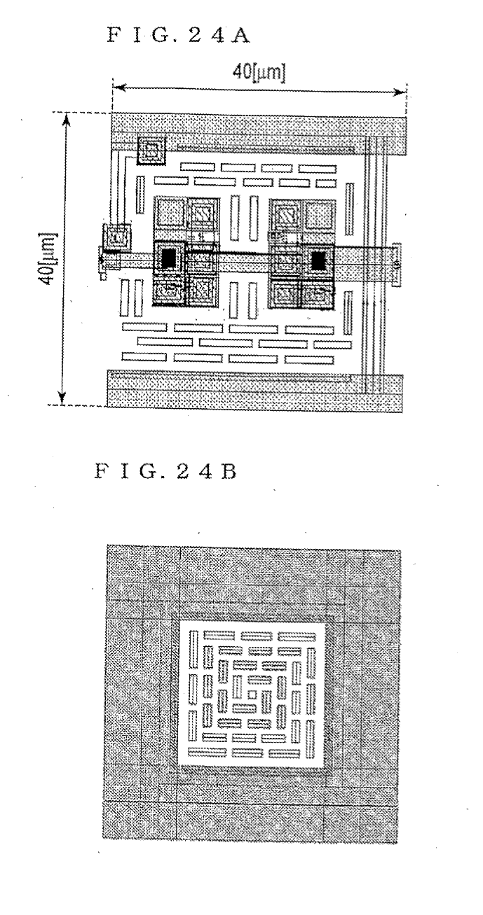

FIG. 25 is a conceptual diagram of a conventional layout;

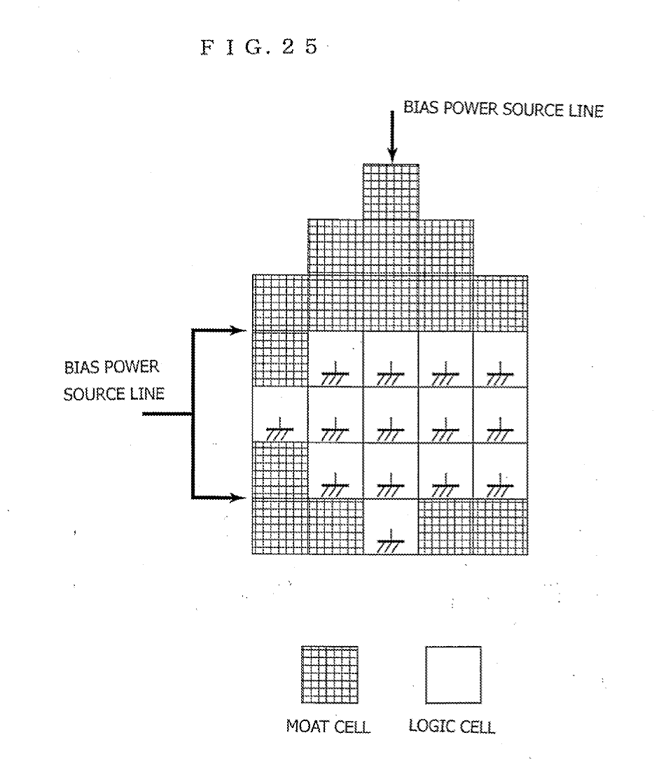

FIG. 26A and FIG. 26B are conceptual diagrams of one example of a conventional DC bias current drawing layout; and

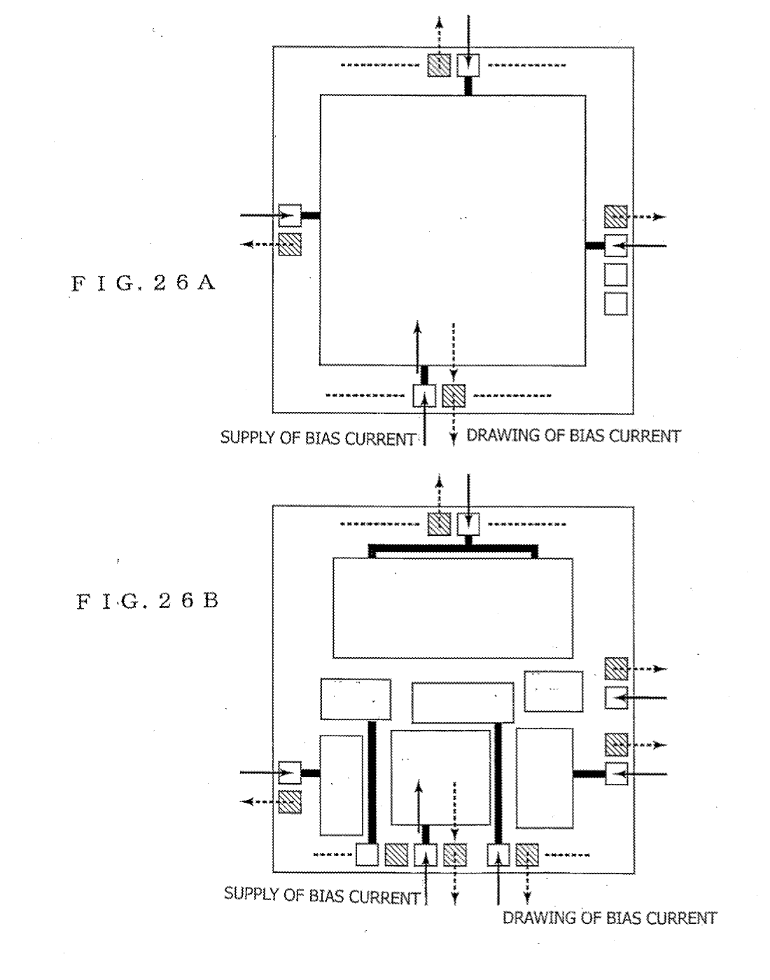

FIG. 27A and FIG. 27B are illustrative diagrams of the path of the return current of the DC bias current flowing in the ground plane in a conventional layout.

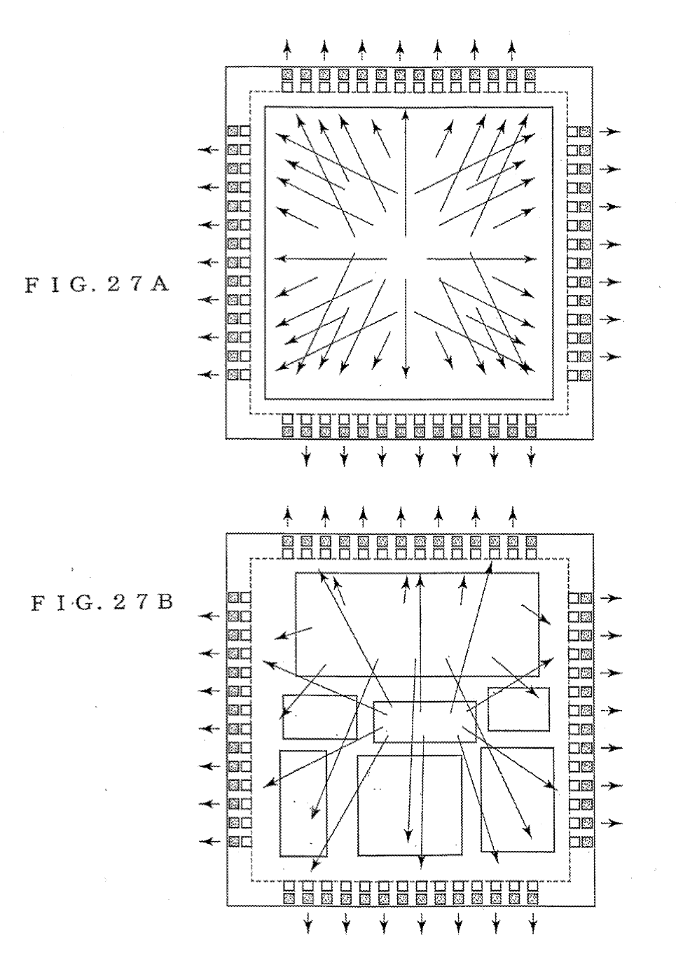

### DESCRIPTION OF EMBODIMENTS

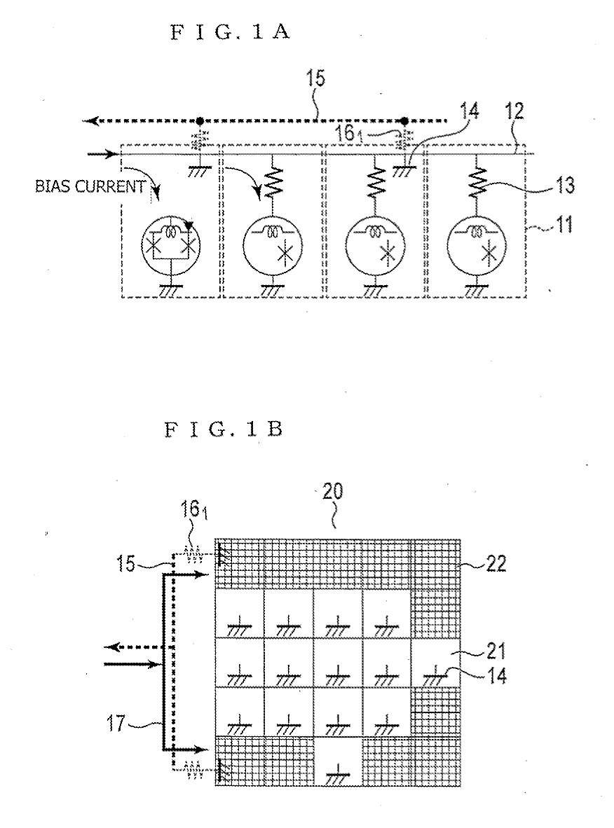

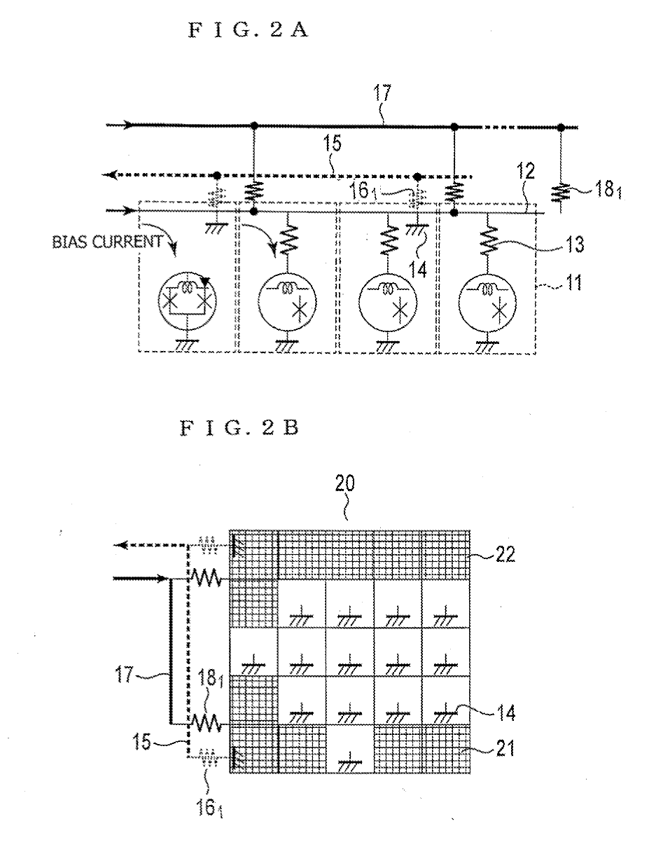

Here, the superconducting single flux quantum integrated circuit device according to an embodiment of the present invention will be described with reference to FIG. 1A and FIG. 1B and FIG. 2A and FIG. 2B. FIG. 1A and FIG. 1B are illustrative schematic drawings of a superconducting single flux quantum integrated circuit device according to an embodiment of the present invention; FIG. 1A is an equivalent circuit diagram of the essential part and FIG. 1B is a layout diagram.

As depicted in FIG. 1A, similarly to the prior art, a bias current is supplied to the SFQ logic gates 11 and the analog circuit, from a DC bias power source line 12 formed from superconducting wire in the SFQ logic gate 11, via a bias resistance 13. In the embodiment of the present invention, furthermore, a bias drawing power source line 15 is connected to the grounds 14 of the plurality of SFQ logic gates 11, via a resistor 16₁ formed from a thin-film resistor having a resistance of 0.1 mΩ to 1Ω, whereby all of the supplied bias current is drawn out.

The ratio of the currents at the respective drawing positions can be controlled by the ratio of the resistance values of the resistors 16₁ which are connected in parallel as depicted by the equivalent circuit. In other words, it is possible to design a functional circuit block 20 in which the ratio of the bias currents drawn out from the respective portions of the periphery of the block is controlled so as to enable stable operation which avoids malfunction and adverse effects, such as lowering of the operating margins.

Furthermore, as depicted in FIG. 1B, in addition to the logic gate cells 21, moat cells 22 for the bias power source and for avoiding circuit malfunction by trapping unwanted magnetic fields are also prepared. In FIG. 1B, a DC bias power source line 17 is connected to two moat cells 22, and the bias drawing power source line 15 is connected via resistors 16₁.

In a functional circuit block 20 which operates stably in this way, the balance between the supply and drawing of the DC bias current is balanced at zero or almost zero. In FIG. 1B, there are two bias current drawing positions, but it is possible to design a functional circuit block 20 so as to operate stably without malfunctions, by providing a plurality of drawing positions as appropriate.

Since a passive transmission line (PTL), such as a micro-strip line or a strip line, is used for transmitting SFQ pulse signals between the functional circuit blocks 20, then no DC bias current is supplied and no current flows in the ground plane, when transmitting the SFQ pulse signals.

Consequently, it is possible to arrange a designed plurality of functional circuit blocks 20 at desired positions inside one superconducting single flux quantum integrated circuit chip, and it is possible readily to design a superconducting single flux quantum integrated circuit chip having desired functions. The supply and drawing of the DC bias current to and from the respective functional circuit blocks 20 can be achieved readily by forming closed circuits via respectively independent DC power sources.

FIG. 2A and FIG. 2B are further illustrative schematic drawings of a superconducting single flux quantum integrated circuit device according to an embodiment of the present invention; FIG. 2A is an equivalent circuit diagram of the essential part and FIG. 2B is a layout diagram. FIG. 2A and FIG. 2B are conceptual diagrams of a case where the concept of controlling the ratio of the bias currents drawn from a plurality of locations in accordance with the ratio of the resistances of the resistors, as illustrated in FIG. 1A and FIG. 1B, is also applied to the bias power source lines 17 which are on the DC bias current supply side.

In other words, when the bonding pads are connected to the bias power source line 12 of the functional circuit block 20 from the main bias power source line 17, a bias current is supplied from a plurality of locations via resistors 18₁ each formed from a thin-film resistor having a resistance of 0.1 mΩ to 1Ω. Furthermore, the ratio of the bias currents from the respective supply locations can be controlled by the ratio of the resistance values of the resistors 18₁ which are connected in parallel, similarly to the case of the bias drawing power source line 15.

In this way, in the embodiment of the present invention, the bias current supplied to the functional circuit blocks inside the superconducting single flux quantum integrated circuit chip flows through the ground and is then drawn out completely from the periphery of the blocks. In this, by controlling the drawing locations of the ground current, and the ratio of the drawing currents from the respective locations, by the arrangement of the resistors and the resistance values thereof, it is possible to eliminate or reduce the effects of the ground currents, on the functional circuit block itself, and on other functional circuit blocks. Furthermore, by this configuration, it is possible to stabilize the circuit operation of the whole single flux quantum integrated circuit chip.

The resistors 16₁, 18₁ may have resistance values of 0.1 mΩ to 1Ω at the operating temperature of the SFQ integrated circuit, and may employ Mo, Ti, Au or a gold alloy, which is used in the formation of the SFQ circuit chip.

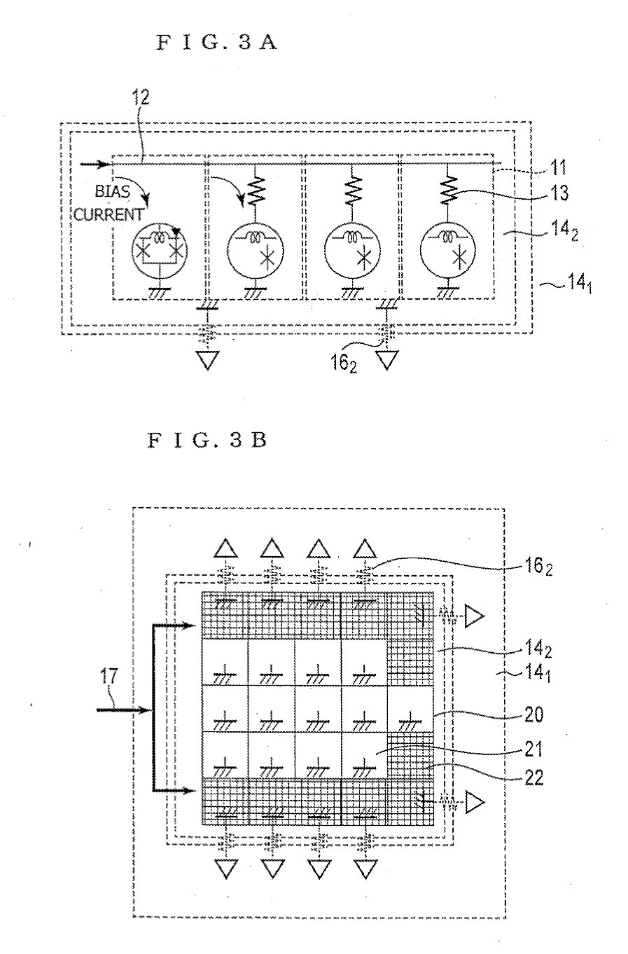

FIG. 3A and FIG. 3B are further illustrative schematic drawings of a superconducting single flux quantum integrated circuit device according to an embodiment of the present invention; FIG. 3A is an equivalent circuit diagram of the essential part and FIG. 3B is a layout diagram. As depicted in FIG. 3A, similarly to the prior art, a bias current is supplied to the SFQ logic gates 11 and the analog circuit, from a DC bias power source line 12 formed from superconducting wire in the SFQ logic gates 11, via bias resistances 13. In the embodiment of the present invention, furthermore, the ground of an SFQ integrated circuit provided with a plurality of SFQ logic gates 11, or a plurality of small-scale functional circuit blocks 20 obtained by dividing up the SFQ integrated circuit, is taken to be a local superconducting ground plane 14₂, which is separate from the main superconducting ground plane 14₁ of the SFQ integrated circuit chip. A DC bias current is supplied from the bias power source line to the SFQ integrated circuit or to each of the functional circuit blocks obtained by dividing same.

Furthermore, thin-film resistors 16₂ having a low total resistance value of 1 μΩ to 0.1Ω are connected between the superconducting ground plane 14₁ and the superconducting ground plane 14₂, and the potential difference between the superconducting ground plane 14₁ and the superconducting ground plane 14₂ is made sufficiently smaller than the voltage amplitude level of the single flux quantum pulses. In other words, the supplied bias current flows to the main superconducting ground plane 14₁ via the thin-film resistors 16₂, and the potential of the local superconducting ground plane 14₂ is slightly higher than the potential of the main superconducting ground plane 14₁. Consequently, it is possible to prevent undesired in-flow of current from the main superconducting ground plane 14₁.

The ratio of the current flowing from the local superconducting ground plane 14₂ to the main superconducting ground plane 14₁ can be controlled by the ratio of the resistance values of the thin-film resistors 16₂ which are connected in parallel as depicted in the equivalent circuit. In this way, it is possible to design a functional block in which the ratio of the bias currents flowing from the respective portions of the periphery of the block is controlled so as to enable stable operation which avoids malfunction and adverse effects, such as lowering of the operating margins.

Furthermore, as depicted in FIG. 3B, in addition to the logic gate cells 21, moat cells 22 for the bias power source and for avoiding circuit malfunction by trapping unwanted magnetic fields are also prepared. In FIG. 3B, a DC bias power source line 17 is connected to two moat cells 22.

A passive transmission line (PTL) such as a micro-strip line or a strip line is used for the transmission of SFQ pulse signals between these functional circuit blocks 20 and the transmission of SFQ pulse signals between the SFQ integrated circuit and an external circuit. Therefore, during the transmission of SFQ pulse signals, no DC bias current is supplied and no current flows in the ground.

For the ground of the transmission lines, it is possible to use the thin-film resistors 16₂ as a pseudo ground layer. Therefore, it is possible to arrange a designed plurality of functional blocks at desired positions inside one SFQ integrated circuit chip and transmit SFQ pulse signals by a transmission line, and a superconducting single flux quantum integrated circuit chip having desired functions can be designed easily.

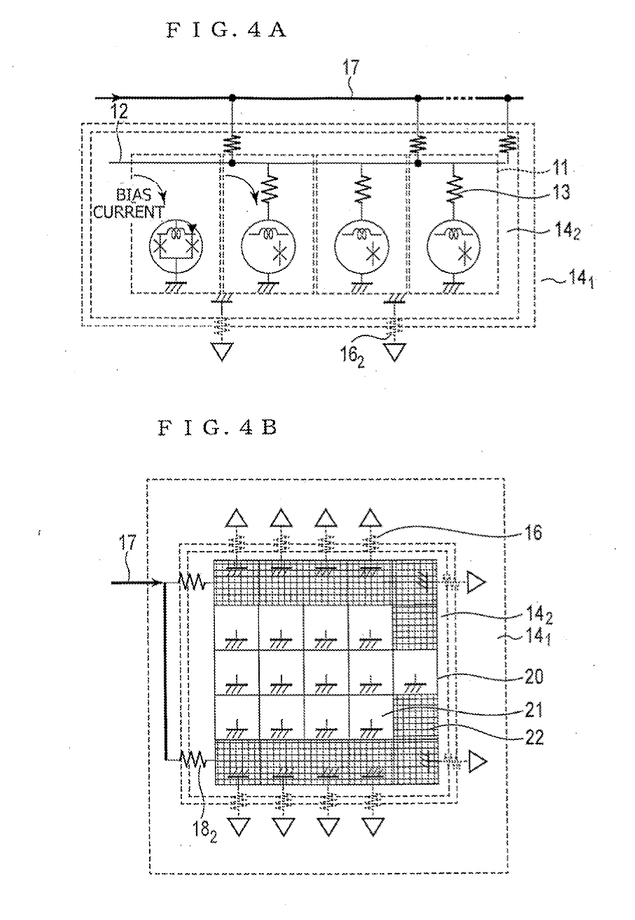

FIG. 4A and FIG. 4B are further illustrative schematic drawings of a superconducting single flux quantum integrated circuit device according to an embodiment of the present invention; FIG. 4A is an equivalent circuit diagram of the essential part and FIG. 4B is a layout diagram. Here, in addition to a composition in which the local ground depicted in FIG. 3A and FIG. 3B is provided and the local ground and the main ground are connected by a thin-film resistor having a low resistance value, the ratio with respect to the DC bias current supply path is controlled via a thin-film resistor having a low resistance value in the bias power source line 17.

In other words, when the bonding pads are connected to the DC bias power source line 12 of the functional circuit block 20 from the main bias power source line 17, a bias current is supplied from a plurality of locations via thin-film resistors 18₂ each having a total resistance of 0.1 mΩ to 0.1Ω. Furthermore, the ratio of the bias currents from the respective supply points can be controlled by the ratio of the resistance values of the thin-film resistors 18₂ which are connected in parallel.

In this way, in a further composition of the embodiment according to the present invention, the bias currents supplied to the functional circuit block 20 in the superconducting single flux quantum integrated circuit chip flow to the chip via a common main superconducting ground plane 14₁, without any mutual effects.

Furthermore, since the local superconducting ground plane 14₂ and the main superconducting ground plane 14₁ are connected via a thin-film resistor 16₂ having a low resistance, then it is possible to eliminate or reduce the effects of the DC ground current from another functional circuit block 20, while enabling the conveyance of SFQ pulses. As a result, it is possible to stabilize the circuit operation of the whole SFQ integrated circuit chip.

The thin-film resistors 16₂ and the respective thin-film resistors 18₂ for bias current supply may each have a total resistance value of 1 μΩ to 0.1Ω and 0.1 mΩ to 0.1Ω, respectively, at the operating temperature of the SFQ integrated circuit. For example, the Mo, Ti, Au or a gold alloy used in the formation of the SFQ circuit chip may be employed.

### FIRST EXAMPLE

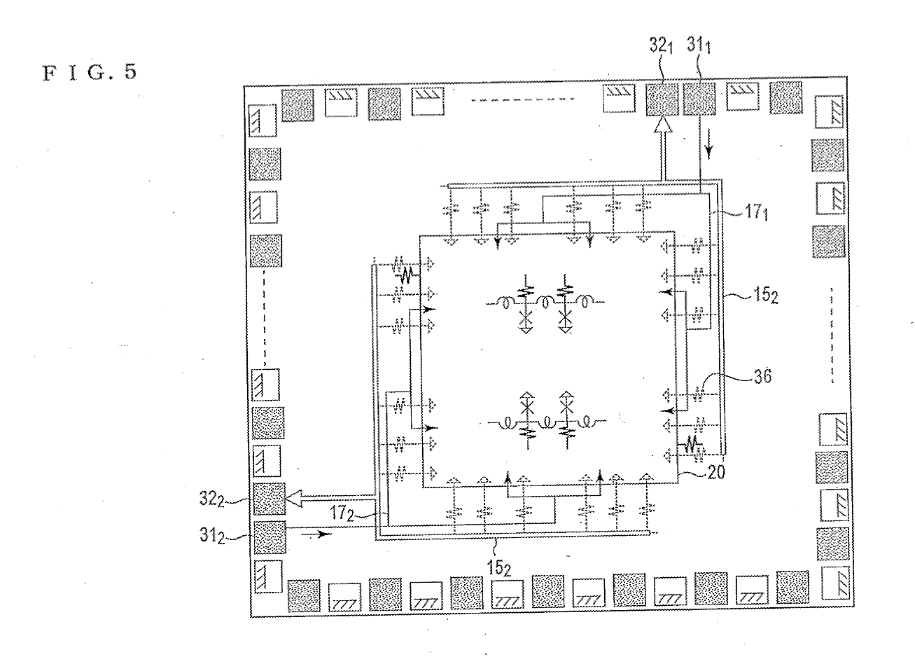

Next, the superconducting single flux quantum integrated circuit device according to a first example of the present invention will be described with reference to FIG. 5. FIG. 5 is a conceptual schematic drawing of a superconducting single flux quantum integrated circuit device according to the first example. Here, a case is given in which a superconducting single flux quantum integrated circuit is constituted by one functional circuit block, and a composition of this kind is adopted when designing a relatively small-scale circuit or a medium-scale circuit appropriately so as to avoid concentration of the bias current.

As depicted in FIG. 5, the plurality of DC bias power source lines 17₁, 17₂ are connected to the bonding pads 31₁, 31₂ for external connection, and are connected from these to a plurality of locations at the periphery of the functional circuit block 20. More specifically, two bonding pads 31₁, 31₂ are connected to two main DC bias power source lines 17₁, 17₂, and the DC bias power source lines 17₁, 17₂ are branched in two and each connected to a total of four locations on two edges of the functional circuit block 20, thereby equalizing the supply of bias current.

On the other hand, the bias drawing power source lines 15₁, 15₂ are wired from the plurality of bonding pads 32₁, 32₂, similarly to the DC bias power source lines 17₁, 17₂. In FIG. 5, two main bias drawing power source lines 15₁, 15₂ are wired from the two bonding pads 32₁, 32₂, and each is branched into two and, on the four edges of the functional circuit block 20, the other ends thereof are connected to the ground plane inside the chip via a thin-film resistor 36 having a resistance value of 0.1 mΩ to 1Ω.

In this way, by the arrangement of the bias drawing power source lines 15₁, 15₂, it is possible to control the ratio of the drawing currents from the locations connected to the ground plane, by the ratio of the resistance values of the thin-film resistors 36 which are connected in parallel.

Furthermore, FIG. 5 depicts a case where thin-film resistors 36 are provided only on the bias drawing power source lines 15₁, 15₂, but as depicted by the conceptual diagram in FIG. 2A and FIG. 2B, it is also possible to provide thin-film resistors having a resistance value from 0.1 mΩ to 1Ω, on the side of the bias power source lines 17₁, 17₂, as well, whereby the supply ratio of the bias currents from the bias supply points around the periphery of the functional circuit block 20 can be controlled. Due to the superconducting wires, the bias power source lines inside the functional circuit block 20 have the same potential, regardless of the ratio of the thin-film resistors.

An external bias current can be supplied from the DC power source, by respectively taking the bonding pads 31₁, 32₁ of the DC bias power source line 17₁ and the bias drawing power source line 15₁ as a pair, and taking the bonding pads 31₂, 32₂ of the DC bias power source line 17₂ and the bias drawing power source line 15₂, as a pair.

By adopting a cell-based design as depicted in FIG. 5, it is possible to equalize the supply of bias current, even if the moat cells provided around the periphery are arranged in multiple levels.

### SECOND EXAMPLE

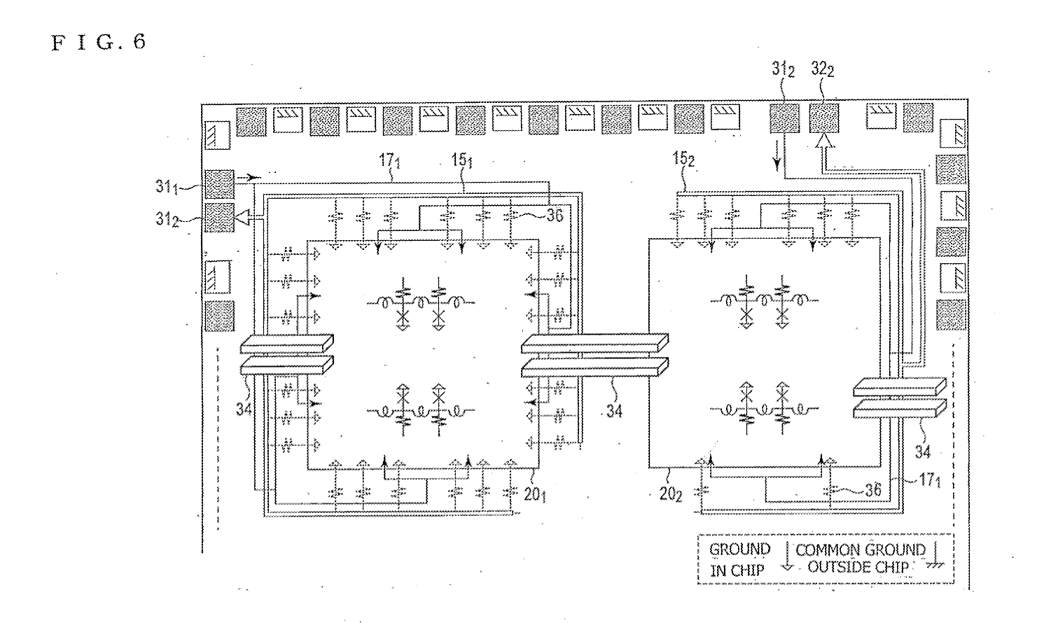

Next, a superconducting single flux quantum integrated circuit device according to a second example of the present invention is described by referring to FIG. 6, but here, an example of a circuit design and layout will be described in which the design is divided into a plurality of relative small-scale functional circuit blocks.

FIG. 6 is a schematic illustrative diagram of a superconducting single flux quantum integrated circuit device according to a second example of the present invention, and depicts an integrated circuit formed from two functional circuit blocks 20₁, 20₂. The bias current is drawn to the outside of the chip via thin-film resistors 36, one end of which is connected to a drawing ground, similarly to the first embodiment, and through bias drawing power source lines 15₁, 15₂, around the periphery of the functional circuit blocks 20₁, 20₂.

By adopting small-scale functional circuit blocks 20₁, 20₂ of this kind, it is possible to eliminate or reduce the effects of the magnetic fields caused by the bias currents and ground currents inside the blocks. Furthermore, a design which controls the bias current supply locations and drawing current locations, and the amount of the currents at the locations, can be achieved easily, and the stable operation of the functional circuit blocks 20₁, 20₂ can be guaranteed readily.

Furthermore, a passive transmission line (PTL) 34, such as a micro-strip line or a strip line, is used as a connection for propagating SFQ pulses between the functional circuit blocks 20₁, 20₂. In the case of micro-strip lines, a superconducting ground plane is used, but no DC bias current flows therein.

By this structure, in principle, the supplied bias current is drawn out completely from each of the respective functional circuit blocks 20₁, 20₂, and DC current does not leak and flow out to the peripheral superconducting ground plane. Consequently, it is possible to avoid mutual effects between the DC bias currents of the functional circuit blocks 20₁, 20₂.

In FIG. 6, a case is depicted in which the bias drawing power source lines 15₁, 15₂ are provided with thin-film resistors 36, but as depicted by the conceptual diagrams in FIG. 2A and FIG. 2B, it is also possible to provide similar thin-film resistors on the bias power source lines 17₁, 17₂, as well. Consequently, it is also possible to control the supply ratio of the bias currents from the plurality of locations around the periphery of the functional circuit blocks 20₁, 20₂.

### THIRD EXAMPLE

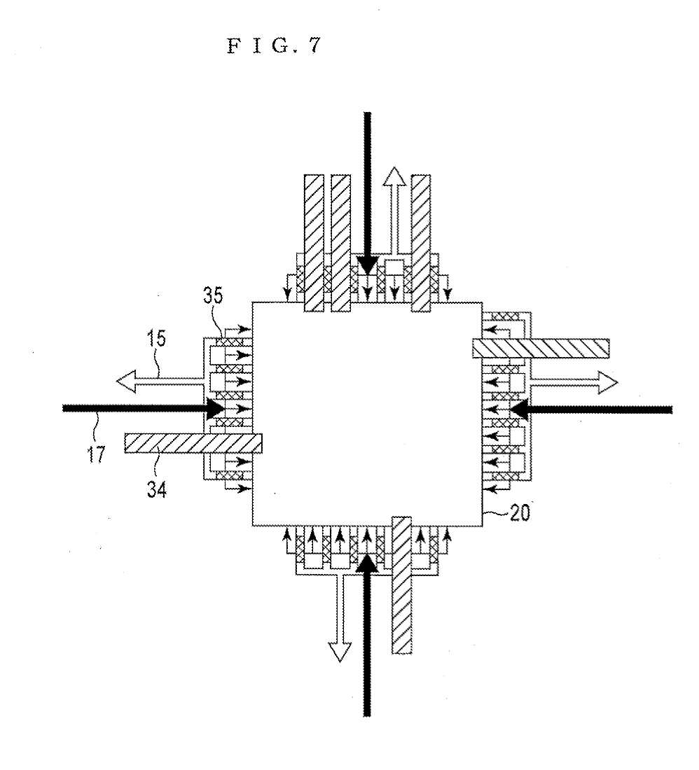

Next, the superconducting single flux quantum integrated circuit device of a third example of the present invention will be described with reference to FIG. 7, but here, the method of connecting the relatively small-scale functional circuit blocks and the bias drawing power source lines will be described.

FIG. 7 is a conceptual schematic drawing of the region of one functional circuit block in a superconducting single flux quantum integrated circuit device according to a third example of the present invention, in which a DC bias current is supplied by a DC bias power source line 17 from all four edges of a functional circuit block 20 which is arranged in a square shape. Furthermore, a composition is adopted in which the bias currents supplied respectively from each edge flowing in the ground are drawn out by bias drawing power source lines 15 which connect to the ground inside the chip via thin-film resistors 37.

By this composition, cancelling out of the supply and drawing of the bias currents can be achieved more readily. In FIG. 7, thin-film resistors 37 having a low resistance value are provided only in the bias drawing power source lines 15, but it is also possible to control the supply ratio of the bias currents from a plurality of locations around the periphery of the functional circuit block 20, by providing similar thin-film resistors on the side of the DC bias power source lines 17 as well.

### FOURTH EXAMPLE

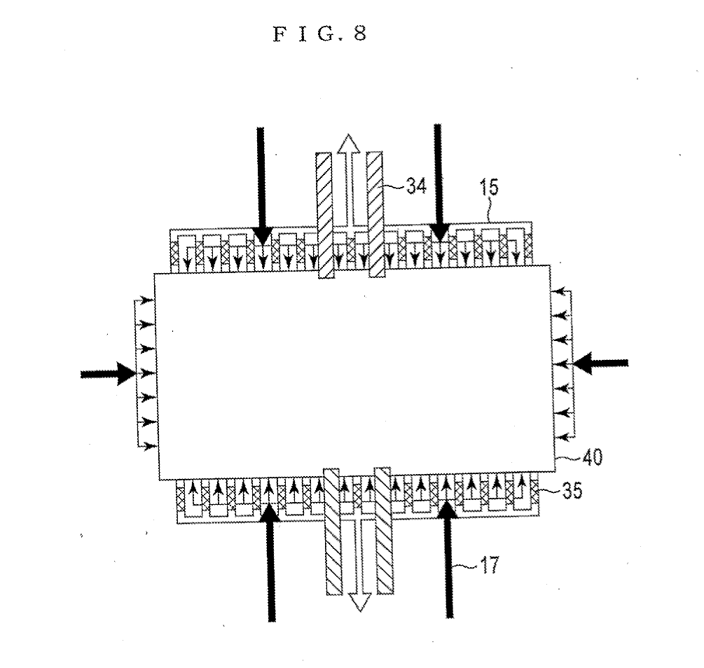

Next, the superconducting single flux quantum integrated circuit device of a fourth example of the present invention will be described with reference to FIG. 8, and here, the method of connecting the relatively small-scale functional circuit blocks and the bias drawing power source lines will be described.

FIG. 8 is a conceptual schematic drawing of the region of one functional circuit block in a superconducting single flux quantum integrated circuit device according to a fourth example of the present invention, in which a DC bias current is supplied by a DC bias power source line 17 from all four edges of a functional circuit block 40 which is arranged in a rectangular shape. Furthermore, a composition is adopted in which the bias currents supplied respectively from each edge flowing in the ground are drawn out by bias drawing power source lines 15 which connect to the ground inside the chip via thin-film resistors 37, on the pair of longer edges.

Basically, according to this composition, the supply and drawing of the bias currents is cancelled out, but it is also possible to use bias supply only from the pair of longer edges, on the upper and lower sides, depending on the compositional details of the functional circuit block 40. In this way, the connections between the DC bias power source lines 17 and the bias drawing power source lines 15 of the respective functional blocks, and the functional circuit block 40, can be designed as desired.

Therefore, it is possible to achieve an optimal design of the small-scale functional circuit blocks, and by combining these, to achieve a medium-scale or large-scale single flux quantum integrated circuit device which operates stably. In FIG. 8, thin-film resistors 37 having a low resistance value are provided only in the bias drawing power source lines 15, but it is also possible to control the supply ratio of the bias currents from a plurality of locations around the periphery of the functional circuit block 40, by providing similar thin-film resistors on the side of the DC bias power source lines 17 as well.

### FIFTH EXAMPLE

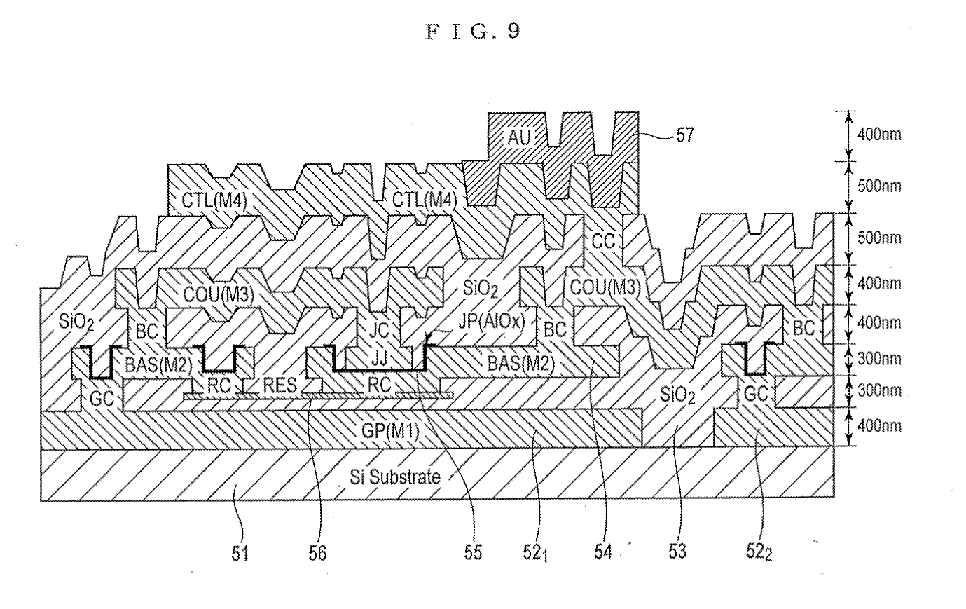

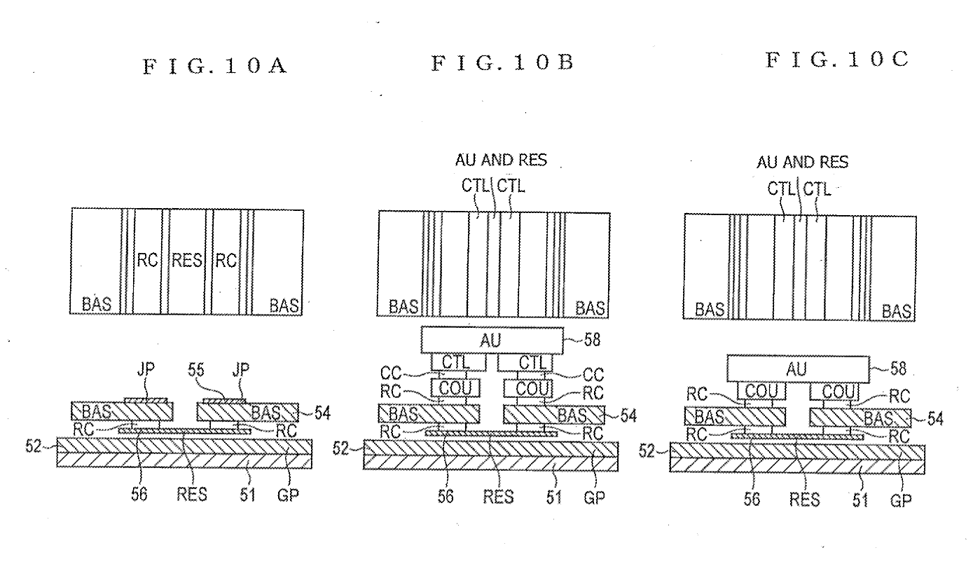

Next, the superconducting single flux quantum integrated circuit device according to a fifth example of the present invention will be described with reference to FIG. 9 and FIG. 10A to FIG. 10C, and here, the specific element structure and wiring structure will be explained. FIG. 9 is a cross-sectional diagram of a superconducting single flux quantum integrated circuit device based on a Nb multiple-layer thin-film process which employs an Nb/AlOₓ/Al/Nb Josephson junction (see, for example, Non-Patent Literature 4 described above).

As depicted in FIG. 9, grounds 52₁, 52₂ are formed by using an Nb superconductor on a silicon substrate 51. Next, after forming a SiO₂ film 53 which is to become an interlayer insulating film, a resistor 56 is formed by Mo. Furthermore, a Josephson junction 55 having a Nb/AlOx/Al/Nb structure is formed by providing AlOₓ/Al between a lower electrode and an upper electrode made from a Nb superconductor 54. Moreover, after forming the Nb superconductor and the interlayer insulating film as depicted in FIG. 9, an Au layer 57 connected to the Nb superconductor is provided.

FIG. 10A to FIG. 10C are schematic drawings of a thin-film resistor which is used in a superconducting SFQ circuit; FIG. 10A is a case where the resistor is made from Mo, and FIG. 1013 and FIG. 10C depict a case where a parallel connection is made using Mo and a portion of an Au film 58 which is deposited when forming an Au layer 57. Here, FIG. 1013 depicts a case where the Nb superconductor (CTL layer) in the uppermost layer and the Au layer are connected, and FIG. 10C depicts a case where the wiring layer (COU layer) on the Josephson junction and the Au layer are connected. The upper drawing in each diagram is a partial perspective plan diagram, and the lower drawing is a cross-sectional diagram of the essential part.

In the fifth example of the present invention, a structure of this kind is used to form a thin-film resistor for bias drawing. In the case of the structure depicted in FIG. 10A, Mo is used, and a resistance having a low resistance value for bias drawing can be achieved by forming the film with a large width compared to the length thereof. In this process, a gold sputter film or a gold plating film are used on the surface of the external connection pads.

Furthermore, in the case of the structure depicted in FIG. 10B or FIG. 10C, it is possible to further reduce the resistance value by using an Au film 58 as the thin-film resistor. In this case, a structure is adopted which also employs an Mo resistance connected in parallel, but the use of Mo may be optional, since a resistor having a sufficiently low resistance value can be achieved by using the Au film 58 alone.

Furthermore, these thin-film resistors can also be used as thin-film resistors for bias current distribution which are provided in the DC bias power source lines. Here, a practical example of an Nb process is depicted, but provided that integrated circuit technology using NbN or multiple-layer thin film structure can be used, it is also possible to employ an integrated circuit process based on a high-temperature superconducting material, such as YBCO, or an iron-type superconducting material.

### SIXTH EXAMPLE

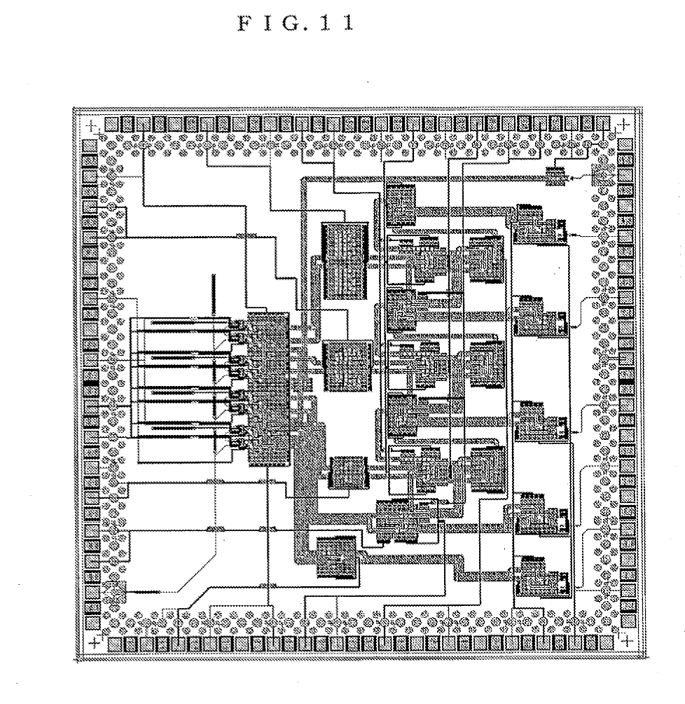

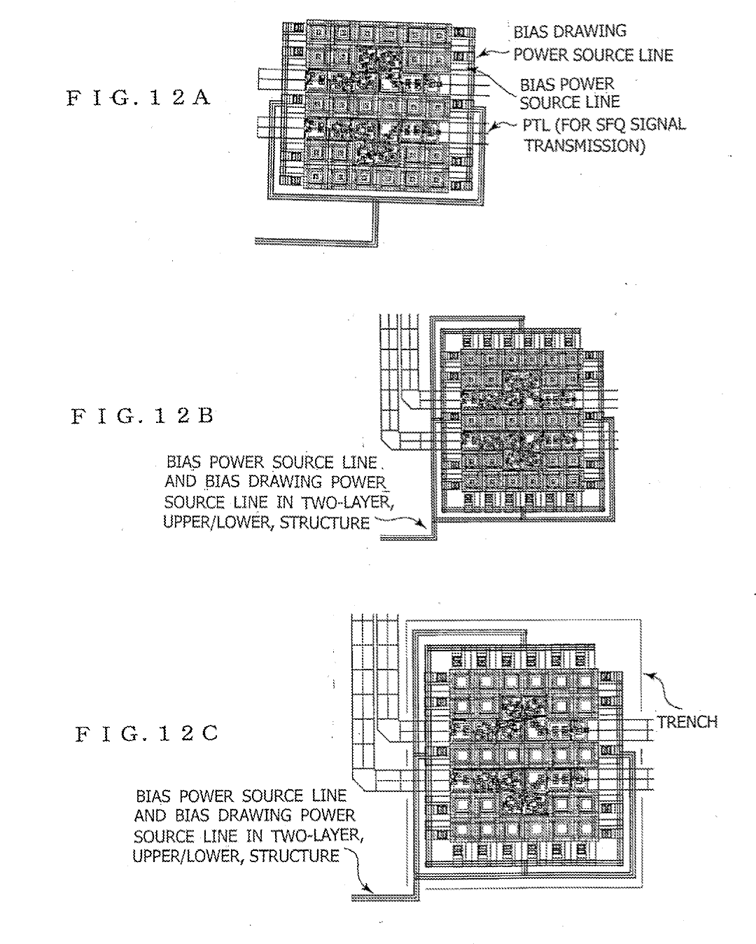

Next, the superconducting single flux quantum integrated circuit device according to a sixth example of the present invention will be described with reference to FIG. 11 and FIG. 12A to FIG. 12C; FIG. 11 is a general schematic drawing of the layout of the superconducting single flux quantum integrated circuit device according to a sixth example of the present invention, depicting an example of an analog/digital conversion circuit which is laid out according to a cell-based design, assuming that an Nb process is employed.

As depicted in the drawings, each small-scale functional circuit block is designed independently, and SFQ pulse signals are transmitted between the functional circuit blocks by using a micro-strip line. A large number of moat cells are provided around the periphery of the logic gate cells, and these moat cells are connected to a DC bias power source line, whereby a bias current is supplied. Furthermore, a bias current is drawn from the bias drawing power source line via other wiring layers of the moat cells and bias drawing resistances which are connected to the ground plane.

FIG. 12A to FIG. 12C are schematic drawings of the layout of respective functional circuit blocks of the superconducting single flux quantum integrated circuit device according to a sixth example of the present invention. FIG. 12A depicts an example in which supply and drawing of bias current is performed from two opposing surfaces of the functional circuit block, and FIG. 12B depicts an example in which supply and drawing of bias current is performed from the four surfaces of the functional circuit block. Furthermore, FIG. 12C is an example in which a bias current is supplied and drawn from four surfaces of the functional circuit block, and a ground trench is provided around the periphery of the functional circuit block.

As depicted in FIG. 12A to FIG. 12C, the DC bias power source lines and the bias drawing lines have a two-layer, upper and lower, structure, and the magnetic fields created by the currents flowing therein cancel each other out. In the present invention, in principle, the bias current supplied from the DC bias power source line is drawn out completely from the bias drawing power source line, and current does not flow around the periphery thereof.

Furthermore, as depicted in FIG. 12C, by providing a trench (narrow groove) in the ground plane so as to surround the outer perimeter of the functional circuit block, then it is possible to control the path of the current flowing on the ground plane, and effects on or from external elements can be prevented doubly.

### SEVENTH EXAMPLE

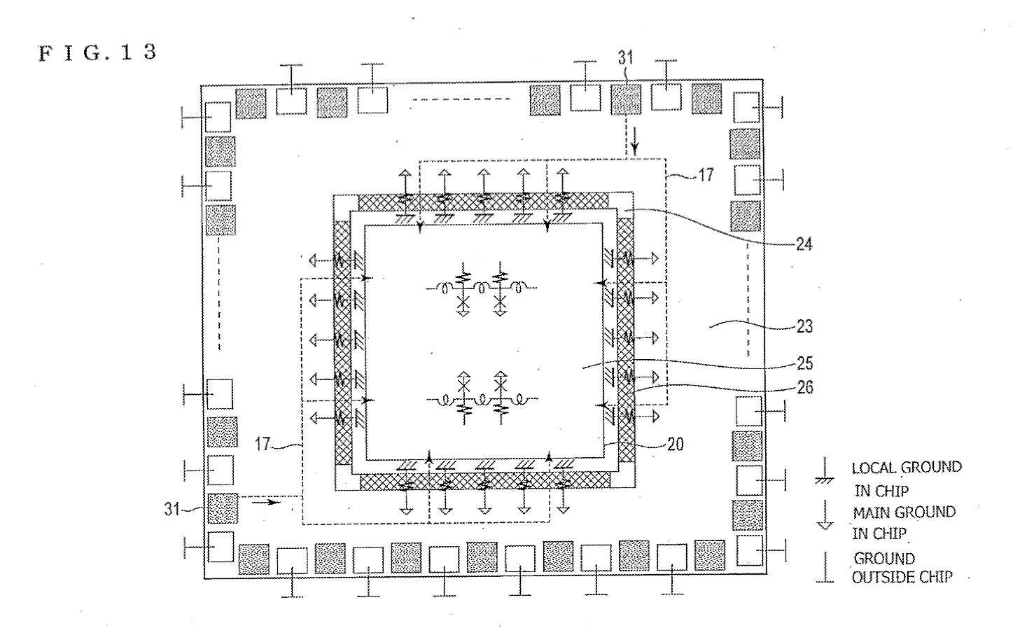

Next, the superconducting single flux quantum integrated circuit device according to a seventh example of the present invention will be described with reference to FIG. 13. FIG. 13 is a conceptual schematic drawing of a superconducting single flux quantum integrated circuit device according to a seventh example. Here, a case is given in which a superconducting single flux quantum integrated circuit is constituted by one functional circuit block, and a composition of this kind is adopted when designing a relatively small-scale circuit or a medium-scale circuit appropriately so as to avoid concentration of the bias current.

As depicted in FIG. 13, a plurality of DC bias power source lines 17 are connected to bonding pads 31 for external connection, and are connected from these to a plurality of locations at the periphery of the functional circuit block 20. More specifically, two bonding pads 31 are connected to two main DC bias power source lines 17, and the DC bias power source lines 17 are branched in two and each connected to a total of four locations on two edges of the functional circuit block 20, thereby equalizing the supply of bias current.

In this seventh example, a trench 24 is provided in the ground plane around the periphery of the functional circuit block 20, in order to separate the main superconducting ground plane 23 which is the common ground plane of the chip, and the superconducting connection. The separated local superconducting ground planes 25 of the functional circuit blocks 20 and the main superconducting ground plane 23 of the chip are connected by a thin-film resistor 26 having a total resistance value of 0.1 mΩ, for example.

The DC bias current supplied to the functional circuit block 20 flows to the main superconducting ground plane 23 of the chip via the thin-film resistor 26. In this, the local superconducting ground plane 25 of the functional circuit block 20 has a potential slightly higher, for, instance, 0.01 mV higher, than the main superconducting ground plane 23.

Furthermore, by providing a thin-film resistor having a resistance value of 1 mΩ, for example, on the side of the bias power source line 17, as depicted in the conceptual diagram in FIG. 4A and FIG. 4B, it is possible to control the supply ratio of the bias currents from the bias supply points around the periphery of the functional circuit block 20. Due to the superconducting wires, the bias power source lines inside the functional circuit block 20 have the same potential, regardless of the ratio of the thin-film resistors.

By adopting a cell-based design as depicted in FIG. 13, it is possible to equalize the supply of bias current, even if the moat cells provided around the periphery are arranged in multiple levels.

### EIGHTH EXAMPLE

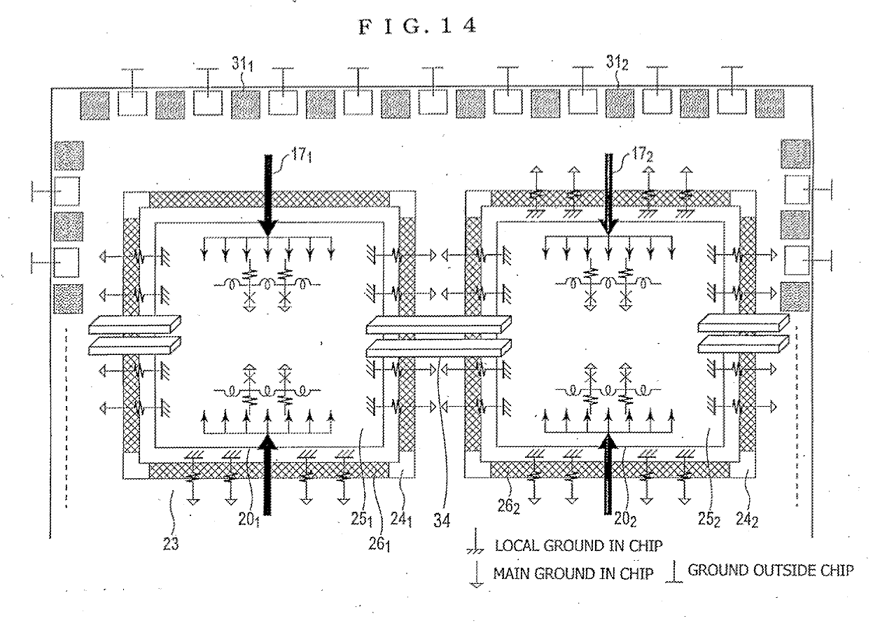

Next, a superconducting single flux quantum integrated circuit device according to an eighth example of the present invention is described by referring to FIG. 14, and here, an example of a circuit design and layout will be described in which the design is divided into a plurality of relatively small-scale functional circuit blocks.

FIG. 14 is a schematic illustrative diagram of a superconducting single flux quantum integrated circuit device according to an eighth example of the present invention, and depicts an integrated circuit formed from two functional circuit blocks 20₁, 20₂. Trenches 24₁, 24₂ are provided in the ground plane around the periphery of the functional circuit blocks 20₁, 20₂ in order to separate the main superconducting ground plane 23 which is the common ground plane of the chip, and the superconducting connection, similarly to the seventh example. The separated local superconducting ground planes 25₁, 25₂ of the functional circuit blocks 20 and the main superconducting ground plane 23 of the chip are connected by thin-film resistors 26₁, 26₂ having a total resistance value of 0.1 mΩ, for example.

By adopting small-scale functional circuit blocks 20₁, 20₂ of this kind, it is possible to eliminate or reduce the effects of magnetic fields caused by the bias currents and ground currents in the block. Furthermore, a design which controls the bias current supply locations and out-flow locations to the main superconducting ground plane 23, and the amount of the currents at the locations, can be achieved easily, and the stable operation of the functional circuit blocks 20₁, 20₂ can be guaranteed readily.

Furthermore, a passive transmission line (PTL) 34, such as a micro-strip line or a strip line, is used as a connection for propagating SFQ pulses between the functional circuit blocks 20₁, 20₂.

By this structure, in principle, the supplied bias current flows to the main superconducting ground plane 23. In so doing, the local superconducting ground planes 25₁, 25₂ of the respective functional circuit blocks 20 are set to a slightly higher potential than the main superconducting ground plane 23, and therefore DC current which has flowed in the common main superconducting ground plane 23 does not flow in from other logic blocks 20₁, 20₂. Consequently, it is possible to avoid mutual effects between the DC bias currents of the functional circuit blocks 20₁, 20₂ on the local superconducting ground planes 25₁, 25₂.

Furthermore, thin-film resistors having a resistance value of 1 mΩ, for example, may be provided on the side of the bias power source line 17₁, 17₂, as depicted in the conceptual diagram in FIG. 4A and FIG. 4B, whereby it is possible to control the supply ratio of the bias currents from a plurality of locations around the periphery of the functional circuit block 20₁, 20₂.

### NINTH EXAMPLE

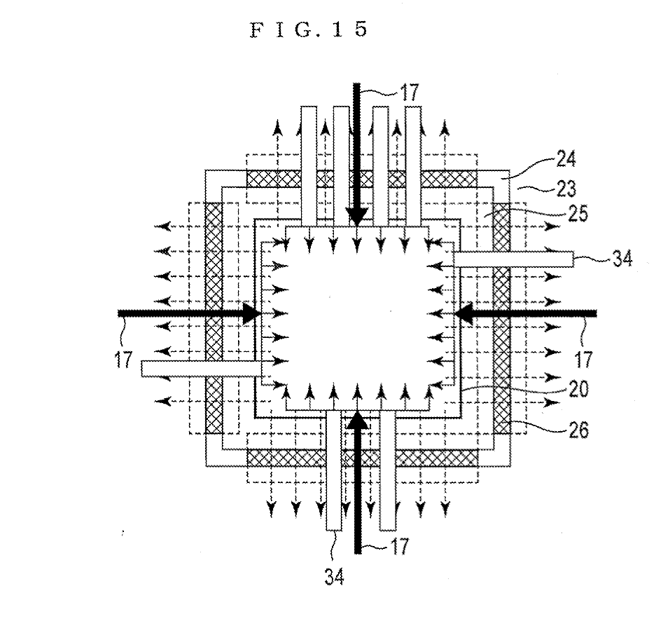

Next, the superconducting single flux quantum integrated circuit device of a ninth example of the present invention will be described with reference to FIG. 15, but here, the method of connecting the local superconducting ground planes and the main superconducting ground plane will be described.

FIG. 15 is a conceptual schematic drawing of the region of one functional circuit block in a superconducting single flux quantum integrated circuit device according to a ninth example of the present invention, in which a DC bias current is supplied by a DC bias power source line 17 from all four edges of a functional circuit block 20 which is arranged in a square shape. Furthermore, a layout is adopted whereby the bias currents supplied from the respective edges flow out to the main superconducting ground plane 23 via the thin-film resistor 26. This thin-film resistor 26 is made from a single solid pattern, but effectively acts as a plurality of resistors connected in parallel.

Furthermore, by providing a thin-film resistor having a resistance value of 1 mΩ, for example, on the side of the DC bias power source line 17, as depicted in the conceptual diagram in FIG. 4A and FIG. 4B, it is also possible to control the supply ratio of the bias currents from the plurality of locations around the periphery of the functional circuit block 20.

### TENTH EXAMPLE

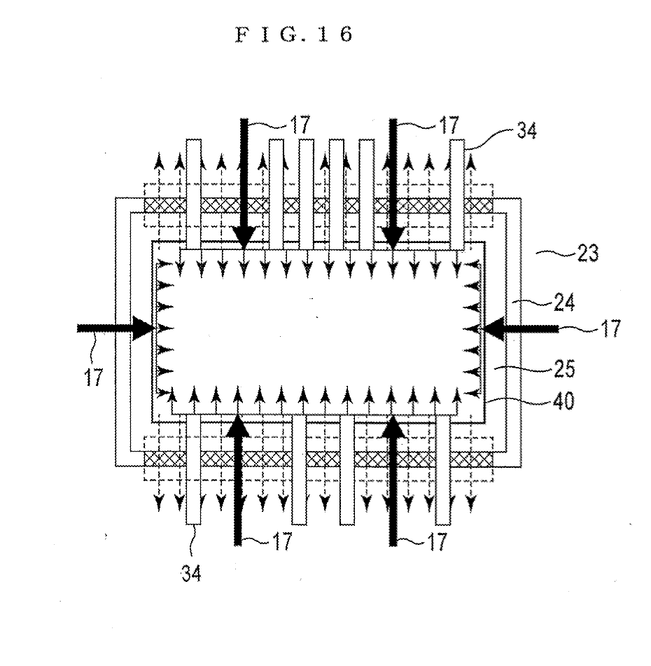

Next, the superconducting single flux quantum integrated circuit device of a tenth example of the present invention will be described with reference to FIG. 16, but here, the method of connecting the local superconducting ground planes and the main superconducting ground plane will be described.

FIG. 16 is a conceptual schematic drawing of the region of one functional circuit block in a superconducting single flux quantum integrated circuit device according to a tenth example of the present invention, in which a DC bias current is supplied by DC bias power source lines 17 from all four edges of a functional circuit block 40 which is arranged in a rectangular shape. Furthermore, the bias currents supplied from the respective edges flow from the pair of longer edges to the main superconducting ground plane 23, via thin-film resistors 26. The thin-film resistors 26 are each made from a single solid pattern, but effectively act as a plurality of resistors connected in parallel.

Depending on the compositional details inside the functional circuit block 40, it is also possible to eliminate the supply of current from the left and right-hand sides, and to supply the bias current from the pair of longer edges on the upper and lower sides, only. Therefore, it is possible to achieve an optimal design of the small-scale functional circuit blocks, and by combining these, to achieve a medium-scale or large-scale single flux quantum integrated circuit device which operates stably.

Furthermore, by providing a thin-film resistor having a resistance value of 1 mΩ, for example, on the side of the DC bias power source lines 17, as depicted in the conceptual diagram in FIG. 4A and FIG. 4B, it is also possible to control the supply ratio of the bias currents from the plurality of locations around the periphery of the functional circuit block 40.

### ELEVENTH EXAMPLE

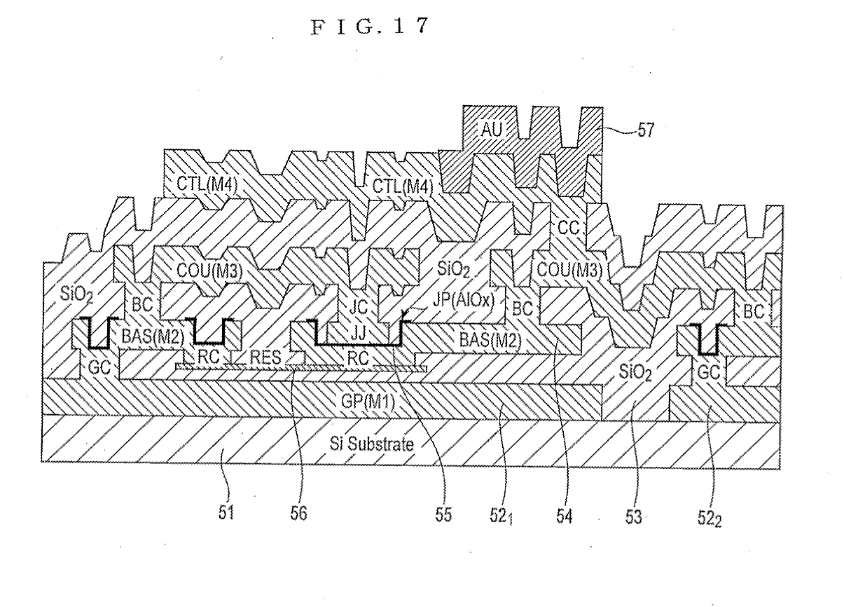

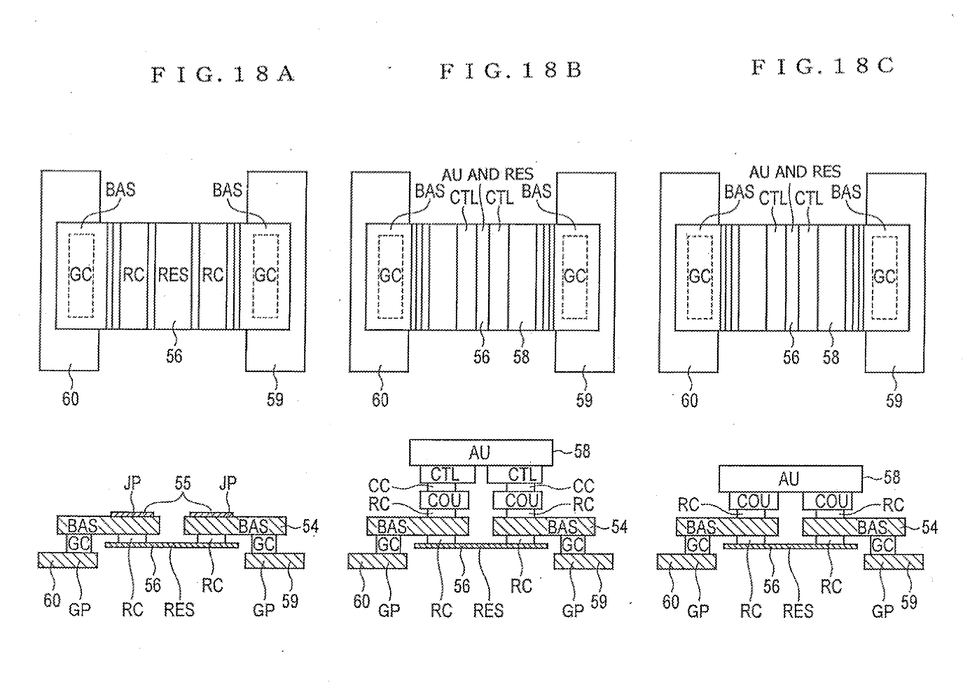

Next, the superconducting single flux quantum integrated circuit device according to an eleventh example of the present invention will be described with reference to FIG. 17 and FIG. 18A to FIG. 18C, and here, the concrete element structure and wiring structure will be explained. FIG. 17 is a cross-sectional diagram of a superconducting single flux quantum integrated circuit device based on a Nb multiple-layer thin-film process which employs an Nb/AlOₓ/Al/Nb Josephson junction (see, for example, Non-Patent Literature 3 described above).

As depicted in FIG. 17, grounds 52₁, 52₂ are formed by using an Nb superconductor on a silicon substrate 51. Next, after forming an SiO₂ film 53 which is to become an interlayer insulating film, a resistor 56 is formed by Mo. Furthermore, a Josephson junction 55 having a Nb/AlOx/Al/Nb structure is formed by providing AlOₓ/Al between a lower electrode and an upper electrode made from an Nb superconductor 54. Moreover, after forming the Nb superconductor and the interlayer insulating film as depicted in FIG. 17, an Au layer 57 connected to the Nb superconductor is provided.

FIG. 18A to FIG. 18C are schematic drawings of a thin-film resistor which is used in a superconducting SFQ circuit; FIG. 18A is a case where the resistor is made from Mo, and FIG. 18B and FIG. 18C depict a case where a parallel connection is made using Mo and a portion of an Au film 58 which is deposited when forming an Au layer 57. Here, FIG. 18B depicts a case where the Nb superconductor (CTL layer) in the uppermost layer and the Au layer are connected, and FIG. 18C depicts a case where the wiring layer (COU layer) on the Josephson junction and the Au layer are connected. The upper drawing in each diagram is a partial perspective plan diagram, and the lower drawing is a cross-sectional diagram of the essential part.

In an eleventh embodiment of the present invention, a thin-film resistor 26 which connects the local superconducting ground planes 60 with the main superconducting ground plane 59 is formed using a structure of this kind.

In the case of the structure depicted in FIG. 18A, Mo is used, and a resistance having a low resistance value for connecting the local superconducting ground plane 60 with the main superconducting ground plane 59 can be achieved by forming the film with a large width compared to the length thereof. In this process, a gold sputter film or a gold plating film are used on the surface of the external connection pads.

Furthermore, in the case of the structure depicted in FIG. 18B or FIG. 18C, it is possible to further reduce the resistance value by using an Au film 58 as the thin-film resistor. In this case, a structure is adopted which also employs an Mo resistance connected in parallel, but the use of Mo may be optional, since a resistor having a sufficiently low resistance value can be achieved by using the Au film 58 alone.

Furthermore, these thin-film resistors can also be used as thin-film resistors for bias current distribution which are provided in the DC bias power source lines. Here, a practical example of a Nb process is given, but provided that integrated circuit technology using NbN or multiple-layer thin film structure can be used, it is also possible to employ an integrated circuit process based on a high-temperature superconducting material, such as YBCO, or an iron-type superconducting material.

### TWELFTH EXAMPLE

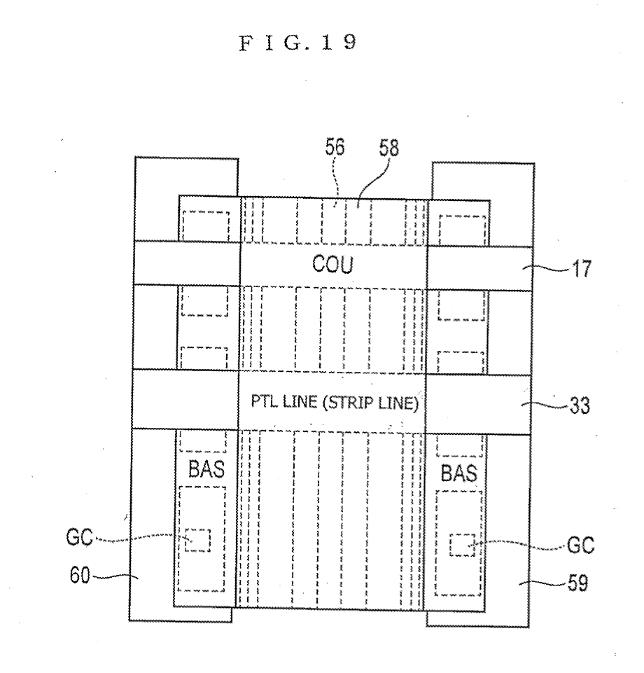

Next, the superconducting single flux quantum integrated circuit device of a twelfth example of the present invention will be described with reference to FIG. 19, and here, a transmission line structure for linking between the local superconducting ground plane and the main superconducting ground plane will be described. FIG. 19 is a partial perspective plan diagram of a transmission line of a superconducting single flux quantum integrated circuit device formed by a Nb multiple-layer thin-film process using an Nb/AlOₓ/Al/Nb Josephson function, and here an example is described in which the transmission line is constituted by a strip line.

A passive transmission line (PTL) is used for transmitting the SFQ pulse signals at high speed, and it is indispensable to transmit signals via the main superconducting ground plane in order to exchange signals between the functional circuit blocks on mutually different local superconducting ground planes.

Consequently, a ground plane continuous above and below the signal line is indispensable for the strip line, but there is a trench between the local superconducting ground plane and the main superconducting ground plane, which are therefore separated in respect of the superconducting wires. However, the local superconducting ground and the main superconducting ground are connected by a resistor having a low resistance value, and this thin-film resistor can be used as a ground plane for the transmission line.

In the twelfth example of the present invention, a transmission line 33 having a strip line structure is formed by using, as upper and lower ground planes, the resistor 56 and the Au film 58 in FIG. 18B which illustrates the eleventh example, and here, an example of one unit cell according to a cell-based design is illustrated. The upper and lower ground planes of the DC bias power source line 17 serve for the bias current which has been supplied to the functional circuit block 20 to flow out to the main superconducting ground plane 59, and are not indispensable above and below the DC bias power source line 17, and may be omitted.

### THIRTEENTH EXAMPLE

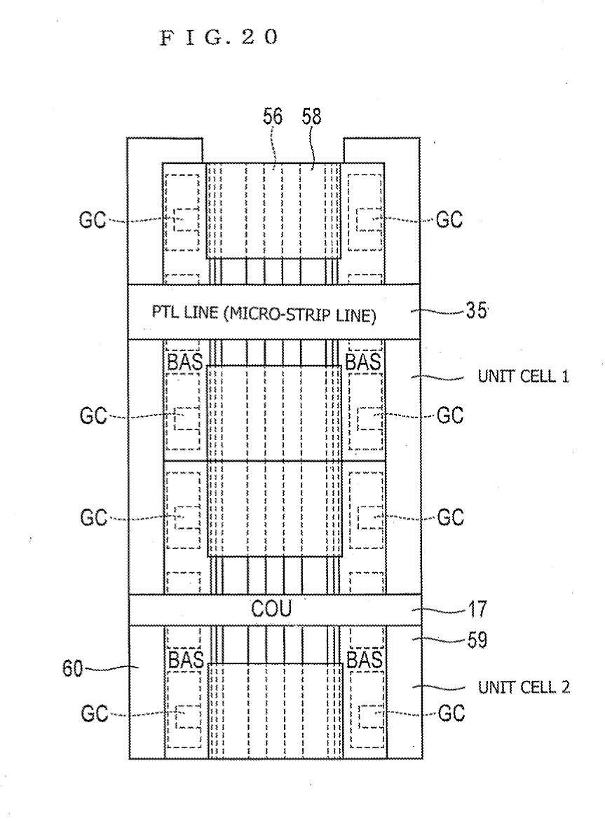

Next, the superconducting single flux quantum integrated circuit device of a thirteenth example of the present invention will be described with reference to FIG. 20, and an example is described here, in which a transmission line for linking between the local superconducting ground plane and the main superconducting ground plane is constituted by a micro-strip line.

In the thirteenth example of the present invention, a transmission line 35 having a micro-strip line structure is formed by using, as a ground plane, only the resistor 56 in FIG. 18B which illustrates the eleventh example, and here, an example of two unit cells according to a cell-based design is illustrated. In this case also, the ground plane below the DC bias power source line 17 serves for the bias current which has been supplied to the functional circuit block 20 to flow out to the main superconducting ground plane 59, and are not indispensable above and below the DC bias power source line 17, and may be omitted.

### FOURTEENTH EXAMPLE

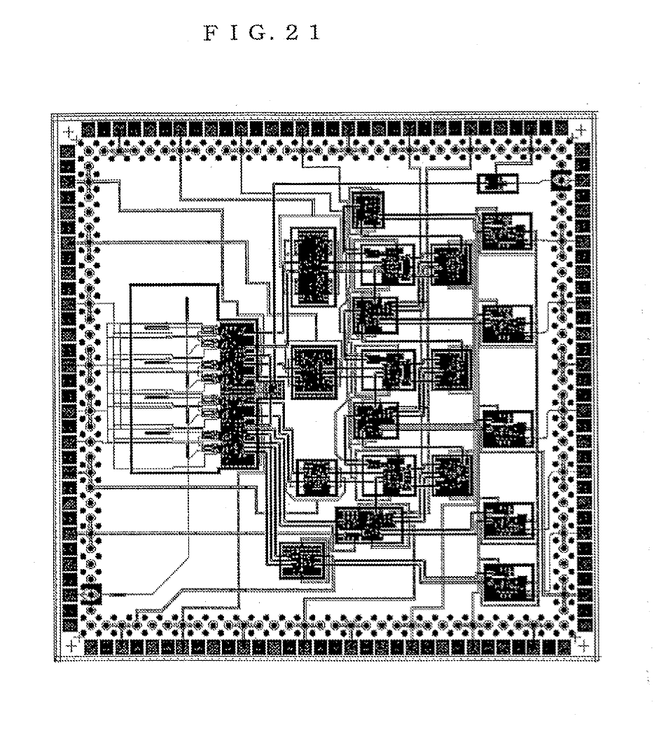

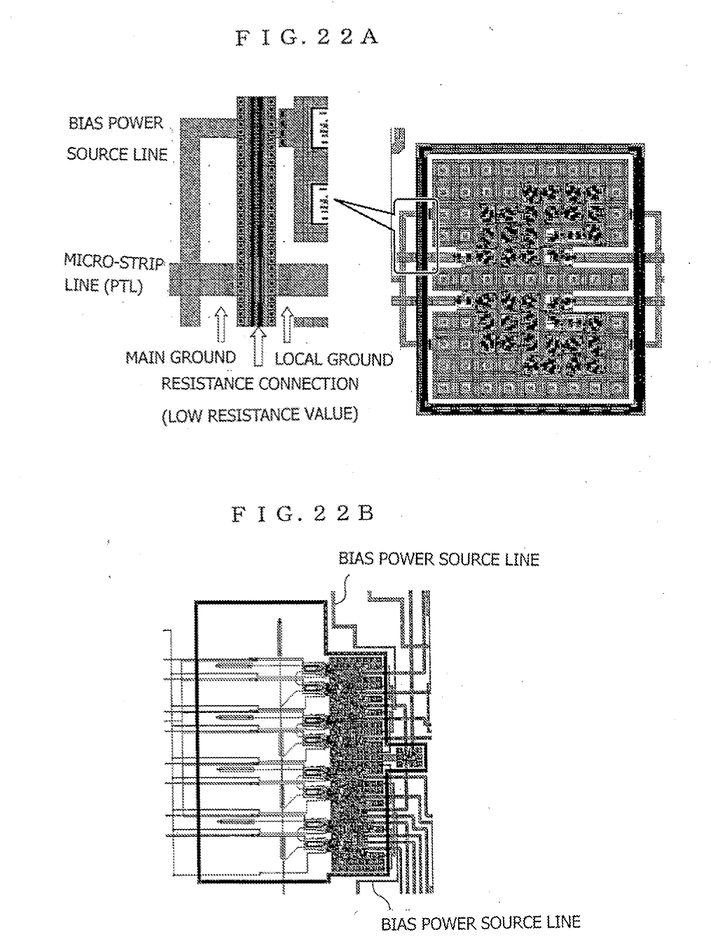

Next, the superconducting single flux quantum integrated circuit device according to a fourteenth example of the present invention will be described with reference to FIG. 21 and FIG. 22A and FIG. 22B; FIG. 21 is a general schematic drawing of the layout of the superconducting single flux quantum integrated circuit device according to a fourteenth example of the present invention, depicting an example of an analog/digital conversion circuit which is laid out according to a cell-based design, assuming that an Nb process is employed.

As depicted in the drawings, each small-scale functional circuit block is designed independently, and SFQ pulse signals are transmitted between the functional circuit blocks by using a micro-strip line. A large number of moat cells are provided around the periphery of the logic gate cells, and these moat cells are connected to a DC bias power source line, whereby a bias current is supplied. Moreover, the DC bias current supplied from the DC bias power source line flows via the thin-film resistor to the main superconducting ground plane, and does not flow to other functional circuit blocks.

FIG. 22A and FIG. 22B are schematic drawings of the layout of respective functional circuit blocks of the superconducting single flux quantum integrated circuit device according to a fourteenth example of the present invention. FIG. 22A depicts an example in which supply of bias current is performed from two opposing surfaces of the functional circuit block, and FIG. 22B depicts an example in which supply of bias current is performed from one surface of the functional circuit block.

1. A superconducting single flux quantum integrated circuit device, comprising:
a bias power source line which supplies a DC bias current to a superconducting single flux quantum integrated circuit in a superconducting single flux quantum integrated circuit chip, from outside the superconducting single flux quantum integrated circuit chip; and
a bias drawing power source line for drawing the DC bias current to the outside of the superconducting single flux quantum integrated circuit chip,
wherein an end of the bias drawing power source line is connected to a ground plane of the superconducting single flux quantum integrated circuit chip via a plurality of resistors formed from thin-film resistors having a resistance value of 0.1 mΩ to 1Ω, at the periphery of a superconducting single flux quantum integrated circuit which is laid out in the superconducting single flux quantum integrated circuit chip, and the DC bias current is drawn out from a contact point with the ground plane.

2. The superconducting single flux quantum integrated circuit device according to claim 1,
wherein the superconducting single flux quantum integrated circuit is divided into a plurality of functional circuit blocks, and the DC bias power source line and the bias drawing power source line are provided for each functional circuit block, and
the bias drawing power source line is connected to a ground plane of the superconducting single flux quantum integrated circuit chip via a plurality of resistors formed from thin-film resistors having a resistance value of 0.1 mΩ to 1Ω, at the periphery of the functional circuit block.

3. The superconducting single flux quantum integrated circuit device according to claim 2, wherein the DC bias power source line and the bias drawing power source line are laid out in such a manner that effectively no current flows to the ground plane at the periphery of the superconducting single flux quantum integrated circuit or the functional circuit blocks.

4. The superconducting single flux quantum integrated circuit device according to claim 2, wherein the plurality of resistors formed from the thin-film resistors are arranged in a parallel connected state around the periphery of the functional circuit blocks, and a drawing path and a drawing ratio of the bias current from the ground plane are controlled by the ratio of the resistance values of the resistors connected in parallel.

5. The superconducting single flux quantum integrated circuit device according to claim 2, wherein the plurality of resistors formed from the thin-film resistors are arranged at any of one to four edges of the periphery of each of the functional circuit blocks, in accordance with the stable operation of the functional circuit block.

6. The superconducting single flux quantum integrated circuit device according to claim 2, wherein a main DC bias power source line leading to the function circuit blocks from a pad for connecting the superconducting single flux quantum integrated circuit chip to an external circuit is branched and connected by the plurality of resistors formed from the thin-film resistors having a resistance value of 0.1 mΩ to 1Ω being connected in parallel to the functional circuit blocks, and the ratio of supply of the bias current from respective supply locations of the DC bias current is controlled by the ratio of the resistance values of the resistors which are connected in parallel.

7. The superconducting single flux quantum integrated circuit device according to claim 1, wherein the resistors formed from the thin-film resistors having a resistance value of 0.1 mΩ to 1Ω are made from any one of Mo, Ti, Au and a gold alloy.

8. The superconducting single flux quantum integrated circuit device according to claim 1, wherein the resistors formed from the thin-film resistors having a resistance value of 0.1 mΩ to 1Ω have a resistance value of 0.1 mΩ to 1Ω at an operating temperature of the superconducting single flux quantum integrated circuit.

9. The superconducting single flux quantum integrated circuit device according to claim 2, wherein the DC bias power source line and the bias drawing power source line leading to the superconducting single flux quantum integrated circuit or the functional circuit blocks from a pad for connecting the superconducting single flux quantum integrated circuit chip to an external circuit are provided above and below respectively or adjacent to each other.

10. A superconducting single flux quantum integrated circuit device, comprising:
a main superconducting ground plane of a superconducting single flux integrated circuit chip;
a local superconducting ground plane separated from the main superconducting ground plane;
a superconducting single flux integrated circuit formed on the local ground plane;
thin-film resistors connected between the main superconducting ground plane and the local superconducting ground plane, and having a total resistance value of 1 μΩ to 0.1Ω; and
a bias power source line which supplies a DC bias to the superconducting single flux integrated circuit.

11. The superconducting single flux quantum integrated circuit device according to claim 10, wherein the superconducting single flux integrated circuit is divided into a plurality of minor functional circuit blocks, the local superconducting ground plane is divided into sub-superconducting ground planes so as to correspond to the divided functional circuit blocks, the thin-film resistors are connected between the divided sub-superconducting ground planes and the main superconducting ground plane, and a DC bias current is supplied to each of the functional circuit blocks from the bias power source line.

12. The superconducting single flux quantum integrated circuit device according to claim 10, wherein the thin-film resistor is provided with either one of a passive micro-strip line or strip line which transmits single flux quantum pulses between the superconducting single flux integrated circuit and the outside, or between the divided functional circuit blocks, such that the thin-film resistor serves as a pseudo ground plane of the micro-strip line or strip line.

13. The superconducting single flux quantum integrated circuit device according to claim 10, wherein a potential difference between the local superconducting ground plane and the main superconducting ground plane due to a bias current supplied to the superconducting single flux integrated circuit is sufficiently low compared to the voltage amplitude level of single flux quantum pulses.

14. The superconducting single flux quantum integrated circuit device according to claim 10, wherein the thin-film resistors are arranged in parallel at the periphery of the superconducting single flux integrated circuit or the divided functional circuit blocks, and a drawing path and a drawing ratio of the bias current are controlled by the ratio of the resistance values of the thin-film resistors which are arranged in parallel.

15. The superconducting single flux quantum integrated circuit device according to claim 10, wherein the thin-film resistors are arranged selectively at any of one to four edges of the periphery of the superconducting single flux integrated circuit or the periphery of each of the divided functional circuit blocks, in accordance with the stabilization of the circuit operation.

16. The superconducting single flux quantum integrated circuit device according to claim 10, wherein a bias power source line leading to the superconducting single flux integrated circuit or the divided functional circuit blocks from a pad for connecting the superconducting single flux integrated circuit chip to an external circuit is branched into a plurality of sub-bias power source lines in the vicinity of the superconducting single flux integrated circuit or the divided functional circuit blocks, the branched sub-bias power source lines and the superconducting single flux integrated circuit or the divided functional circuit blocks are connected in parallel by the thin-film resistors having a total resistance value of 1 mΩ to 0.1Ω, and a supply path and a supply ratio of the bias current are controlled by the ratio of the resistance values of the thin-film resistors connected in parallel.

17. The superconducting single flux quantum integrated circuit device according to claim 10, wherein the thin-film resistors are made from any one of Mo, Ti, Au and a gold alloy.

18. The superconducting single flux quantum integrated circuit device according to claim 10, wherein the thin-film resistors are made from conductive members having a total resistance value of 1 μΩ to 0.1Ω, at an operating temperature of the superconducting single flux quantum integrated circuit.
